(19) United States
(12) Patent Application Publication
(10) Pub. No.: US 2026/0040717 A1
(43) Pub. Date: Feb. 5, 2026

(54) Semiconductor Optical Device

(71) Applicant: Nippon Telegraph and Telephone Corporation, Tokyo (JP)

(72) Inventors: Takuma Tsurugaya, Musashino-shi, Tokyo (JP); Shinji Matsuo, Musashino-shi, Tokyo (JP)

(21) Appl. No.: 19/100,029

(22) PCT Filed: Aug. 5, 2022
(86) PCT No.: PCT/JP2022/030069

§ 371 Date: Jan. 30, 2025

(51) Int. Cl. H10F 77/14; H01S 5/042; H10F 30/222; H10F 77/124; H10F 77/20

(52) U.S. Cl. CPC H10F 77/146; H01S 5/04256; H10F 30/222; H10F 77/1248; H10F 77/147; H10F 77/206

(57) ABSTRACT

The semiconductor optical device first includes a first cladding layer formed on a substrate, a first semiconductor layer of a first conductivity type formed on the first cladding layer, an active layer formed on the first semiconductor layer, and a second semiconductor layer of an i-type or second conductivity type formed on the active layer in contact with the active layer. The semiconductor optical device also includes a plurality of third semiconductor layers of the second conductivity type formed on the second semiconductor layer.

### TECHNICAL FIELD

The present invention relates to a semiconductor optical device.

### BACKGROUND ART

For example, there exists an optical device having a thin-film structure in which a group III-V semiconductor thin film with a thickness of approximately 200 to 400 nm is surrounded by an insulating material having a low refractive index, such as SiO₂ and air. As a structure capable of achieving both strong optical confinement peculiar to the optical device of this thin-film structure and efficient current injection from the vertical direction, there has been proposed a vertical thin-film structure in which a Mesa for current injection having a narrow width (typically 400 nm or less) is arranged on an upper part of an active layer of the thin-film structure (PTL 1).

As an ordinary thin-film structure, the horizontal type has been widely adopted in which lateral semiconductors (for example, InP) on the right and left sides of an embedded active layer composed of a multiple quantum well layer composed of InGaAsP, InGaAlAs, etc. are doped into n-type and p-type, respectively, and carriers are injected from both of them (see NPL 1 to NPL 3). On the other hand, according to the vertical injection type thin-film structure of PTL 1, the Mesa or current injection (hereinafter referred to as a “first Mesa”) on the upper part of the active layer is made to have a narrow width of, for example, approximately 400 nm or less to prevent the mode of light in the cross section of the active layer from being absorbed by the first Mesa, and high optical confinement comparable to the horizontal type can be obtained while enabling current injection from the vertical direction.

### CITATION LIST

### Patent Literature

[PTL 1] WO 2021/199137

### Non Patent Literature

[NPL 1] S. Matsuo et al., “Directly modulated buried heterostructure DFB laser on SiO2/Si substrate fabricated by regrowth of InP using bonded active layer,” Optics Express, vol. 22, No. 10, pp. 12139-12147, 2014.
[NPL 2] S. Yamaoka et al., “Directly modulated membrane lasers with 108 GHz bandwidth on a high-thermal-conductivity silicon carbide substrate,” Nature Photonics, vol. 15, pp. 28-35, 2021.
[NPL 3] E. KANNO et al., “Twin-mirror membrane distributed-reflector lasers using 20-μm-long active region on Si substrates,” Optics Express, vol. 26, No. 2, pp. 1268-1277, 2018.

### SUMMARY OF INVENTION

Technical Problem

In the thin-film structure, it is necessary to keep the thickness at a thin value less than the thickness called the critical film thickness, and when the cross-sectional area of the active layer is desired to be enlarged, the length in the width direction is increased. The expansion of the cross-sectional area of the active layer is important in achieving high power of an active optical device, such as high output in a laser diode (LD), high output in a semiconductor optical amplifier (SOA), and increase in maximum light receivable power in a photodiode (PD).

However, in the conventional vertical type thin-film structure, it is necessary to keep the width of the p-type first Mesa controlling the element resistance at a narrow width such as 400 nm or less as described above, and the first Mesa width cannot be enlarged in accordance with the enlargement of the active layer width. If the first Mesa width is enlarged to 400 nm or more, the mode of light is largely absorbed by the first Mesa, and strong optical confinement into the active layer, which is a characteristic of the thin-film structure, is impaired.

This means that the element resistance per volume of the active layer inevitably increases as the width of the active layer increases, in order to maintain strong optical confinement. For example, in the case of LD or SOA, the amount of current that can be injected is limited by Joule heat generation, and high output is prevented. Further, as the width of the active layer is increased, the distance between the left end and the right end of the active layer and the first Mesa increases, so that the problem of non-uniformity of the carrier distribution is also actualized. For example, in the case of LD or SOA, holes cannot be sufficiently supplied to the end of the active layer, so that the gain becomes uneven, and in the case of PD, photocarriers generated at the end of the active layer cannot be quickly pulled out.

The problems of the element resistance and carrier non-uniformity are common to the horizontal type thin-film structure. In other words, even in the horizontal type as well, the thickness of the p-type region is limited by the critical film thickness, and it is difficult to reduce the element resistance in accordance with the increase of the width of the active layer. Furthermore, since the n-type region and the p-type region are formed at the positions of the counter electrodes across the active layer, the non-uniformity of the electron distribution and the hole distribution becomes remarkable by increasing the width of the active layer.

Therefore, in the conventional thin-film structure, it is difficult to expand the width of the active layer while maintaining the low element resistance per volume of the active layer and the good uniformity of the carrier distribution in both the vertical type and the horizontal type.

The present invention has been made to solve the above-mentioned problems, and an object thereof is to satisfy high optical confinement, a low element resistance per volume of an active layer, good uniformity of current injection distribution over the entire active layer, and uniformity of a mode distribution of light, to expand the width of the active layer.

### Solution to Problem

A semiconductor optical device according to the present invention includes a first cladding layer formed on a substrate, a first semiconductor layer of a first conductivity type formed on the first cladding layer, an active layer formed on the first semiconductor layer, a second semiconductor layer of an i-type or second conductivity type formed on the active layer in contact with the active layer, a plurality of third semiconductor layers of a second conductivity type formed on the second semiconductor layer, a first electrode electrically connected to the first semiconductor layer, a second electrode electrically connected to the plurality of third semiconductor layers, and a second cladding layer formed between the first semiconductor layer and the second electrode, wherein the plurality of third semiconductor layers are arranged in a direction perpendicular to a waveguide direction and parallel to a plane of the substrate.

### Advantageous Effects of Invention

As described above, according to the present invention, since the plurality of third semiconductor layers for current injection are provided on the second semiconductor layer on the active layer, the width of the active layer can be expanded by satisfying high optical confinement, a low element resistance per volume of the active layer, good uniformity of current injection distribution in the entire active layer, and uniformity of a mode distribution of light.

### BRIEF DESCRIPTION OF DRAWINGS

FIG. 1 is a configuration diagram showing a configuration of a semiconductor optical device according to an embodiment of the present invention.

FIG. 2 is a configuration diagram showing a configuration of another semiconductor optical device according to an embodiment of the present invention.

FIG. 3 is a configuration diagram showing a structure used for performing mode calculation for characteristics of a semiconductor optical device.

FIG. 4 is a distribution diagram showing an intensity distribution of a base mode calculated under various third semiconductor layer intervals G.

FIG. 5 is a characteristic diagram showing the relationship between an optical confinement coefficient of an active layer 104 and an interval G between third semiconductor layers adjacent to each other.

FIG. 6 is a configuration diagram showing a structure used for performing mode calculation for characteristics of a semiconductor optical device.

FIG. 7 is a distribution diagram showing an intensity distribution (a) of a TE00 mode and an intensity distribution (b) of a TE10 mode obtained by a calculation.

FIG. 8A is a characteristic diagram showing the relationship between an optical confinement coefficient to the active layer 104 in the TE00 mode and the interval G between the third semiconductor layers adjacent to each other.

FIG. 8B is a characteristic diagram showing the relationship between an optical confinement coefficient to the active layer 104 in the TE10 mode and the interval G between the third semiconductor layers adjacent to each other.

### DESCRIPTION OF EMBODIMENTS

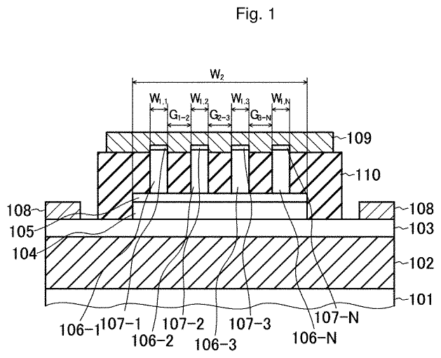

Hereinafter, a semiconductor optical device according to an embodiment of the present invention will be described with reference to FIG. 1. This semiconductor optical device includes, first, a first cladding layer 102 formed on a substrate 101, a first semiconductor layer 103 of a first conductivity type formed on the first cladding layer 102, an active layer 104 formed on the first semiconductor layer 103, and a second semiconductor layer 105 of an i-type or second conductivity type formed on the active layer 104 in contact with the active layer 104. Light is generated in the active layer 104.

The active layer 104 extends from, for example, the front side to the back side (in a waveguide direction) of the page space of FIG. 1. FIG. 1 shows a cross section of a plane perpendicular to the waveguide direction, wherein the plane perpendicular to the waveguide direction is defined as an xy plane, the horizontal direction of the page space of FIG. 1 is defined as an x-direction, the vertical direction of the page space (the lamination direction of each layer) of FIG. 1 is defined as a y-direction, and the waveguide direction (the optical axis direction) is defined as a z-direction. In this example, the active layer 104 and the second semiconductor layer 105 are formed to have the same area in plan view, and the second semiconductor layer 105 overlaps the active layer 104 in plan view.

The semiconductor optical device also includes a plurality of third semiconductor layers 106-1, 106-2, 106-3, 106-N of the second conductivity type formed on the second semiconductor layer 105. The third semiconductor layers 106-1, 106-2, 106-3, 106-N have a structure for vertical current injection. Each of the plurality of third semiconductor layers 106-1, 106-2, 106-3, 106-N has a Mesa shape extending in the waveguide direction (z-direction). The plurality of third semiconductor layers 106-1, 106-2, 106-3, 106-N are arranged in a direction perpendicular to the waveguide direction and parallel to the plane of the substrate 101 (x-direction). The plurality of third semiconductor layers 106-1, 106-2, 106-3, 106-N can be arranged above a formation region of the active layer 104, for example. Further, the plurality of third semiconductor layers 106-1, 106-2, 106-3, 106-N can also be opened outward from the upper part of the formation region of the active layer 104.

In addition, the semiconductor optical device includes a first electrode 108 electrically connected to the first semiconductor layer 103, and a second electrode 109 electrically connected to the plurality of third semiconductor layer 106-1, 106-2, 106-3, 106-N.

In this example, a plurality of contact layers 107-1, 107-2, 107-3, 107-N formed on the plurality of third semiconductor layers 106-1, 106-2, 106-3, 106-N, respectively, are provided. The second electrode 109 is formed on the plurality of third semiconductor layers 106-1, 106-2, 106-3, 106-N via the plurality of contact layers 107-1, 107-2, 107-3, 107-N. The semiconductor optical device also includes a second cladding layer 110 formed between the first semiconductor layer 103 and the first electrode 108.

The substrate 101 can be formed of, for example, silicon. The first cladding layer 102 can be composed of an insulating material such as silicon oxide, for example. The first semiconductor layer 103 can be made of, for example, n-type InP. In this case, the first conductivity type is the n-type, and the second conductivity type is the p-type.

The active layer 104 can be, for example, a multiple quantum well structure resulting from a well layer and a barrier layer composed of InGaAlAs, InGaAs, InGaAsP, and the like, which each have a different composition. The active layer 104 can also be formed by compound semiconductors such as bulk InGaAlAs, InGaAs, and InGaAsP.

The second semiconductor layer 105 can be made of, for example, n-type InP. The second semiconductor layer 105 may be composed of a semiconductor having a refractive index between the third semiconductor layers 106-1, 106-2, 106-3, 106-N and the active layer 104. By constituting the refractive index difference in this manner, a separate confined heterostructure (SCH) structure can be obtained.

The plurality of third semiconductor layers 106-1, 106-2, 106-3, 106-N can be made of p-type InP, for example. The plurality of contact layers 107-1, 107-2, 107-3, 107-N can be made of, for example, p-type InGaAs. The second cladding layer 110 can be made of silicon oxide, for example. The second cladding layer 110 can also be made of, for example, a resin such as benzocyclobutene (BCB).

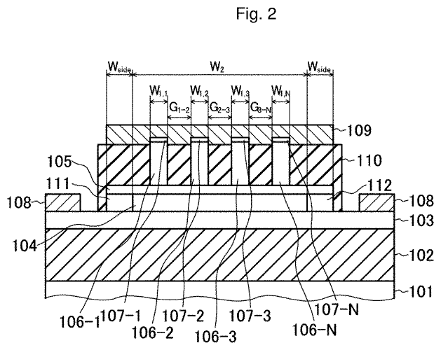

Further, as shown in FIG. 2, a fourth semiconductor layer 111 and a fifth semiconductor layer 112 formed on the first semiconductor layer 103 in contact with both side surfaces of a ridge pattern formed by the active layer 104 can be provided. The fourth semiconductor layer 111 and the fifth semiconductor layer 112 are non-conductive or low-conductive and can be made of, for example, i-type InP (i-InP). In addition, the fourth semiconductor layer 111 and the fifth semiconductor layer 112 may be made of semi-insulating InP (SI-InP) having high resistance by doping Fe.

Although the semiconductor optical device has the third semiconductor layers for hole current injection in the thin-film structure in which the active layer 104 is formed as in PTL 1, the structure in the embodiment is characterized in that the third semiconductor layers 106-1, 106-2, 106-3, 106-N are provided at appropriate intervals. The width of the i-th third semiconductor layer is defined as W_{,1i}, the interval between the i-th third semiconductor layer and the (i+1)-th third semiconductor layer is defined as Gᵢ₋₍ᵢ₊₁₎, and the total number of the third semiconductor layers is defined as N. The width of the active layer 104 is defined as W₂. Based on this definition, it is assumed that “W₂≥(W_{1,1},+ . . . +W_{1,N})+(G₁₋₂+ . . . +G_{(N-1)—N)} . . . (1)” is satisfied in the configuration shown in FIG. 1.

That is, all the third semiconductor layers 106-1, 106-2, 106-3, 106-N are arranged in the upper part of the active layer 104. It is desirable to satisfy the equation (1) in order to efficiently inject a hole current into the active layer 104.

The specific range of each structural parameter is not limited to W₂, and the W₂ can be appropriately set according to a desired optical power scale (i.e., output power of LD, SOA, and light receiving power of PD, for example). Next, the width W_{1,i} of the third semiconductor layer is set to such a value that the base mode of light formed in this structure is not largely absorbed by the plurality of third semiconductor layers, typically, to be approximately 400 nm or less. Within the range satisfying this condition, the widths of the plurality of third semiconductor layers may be equal or different. However, when the symmetry of the current injection distribution in x-direction the is taken into consideration, it is desirable that the condition of “W_{1,i}=W_{1,(N-i+}1)” is satisfied.

Also, as to the interval G_{i,(i+1)} between the third semiconductor layers adjacent to each other as well, a value is set so as to satisfy the condition that the base mode of light is not largely absorbed by the plurality of third semiconductor layers. This also depends on the widths of the third semiconductor layers, but typically is approximately 200 nm or more. Within the range satisfying this condition, the intervals may be equal or different. However, when the symmetry of the current injection distribution in the x-direction is taken into consideration, it is desirable that the condition of “Gᵢ₋₍ᵢ₊₁₎=G_{(N-i)-(N-i+1)}” is satisfied.

The total number N of the third semiconductor layers may be set arbitrarily within the range satisfying the above conditions, but it is desirable to increase the number as much as possible in order to reduce the element resistance per volume of the active layer.

As shown in FIGS. 1 and 2, a region between the third semiconductor layers 106-1, 106-2, 106-3, 106-N is filled with the second cladding layer 110 made of a suitable low refractive index cladding material. Typical examples include polymeric materials having a refractive index of approximately 1.4 to 1.5, which are often used in optical applications in communication wavelength bands (1310 nm band, 1550 nm band). Alternatively, a material such as SiN, for example, may be thinly formed on the surfaces of the third semiconductor layers, the first semiconductor layer 103, the fourth semiconductor layer 111, and the fifth semiconductor layer 112 as a cladding material serving also as passivation of the semiconductor surface, and a polymeric material may be applied thereon. Thus, the contact layer on each third semiconductor layer is exposed on the second cladding layer 110, to enable contact with all the third semiconductor layers by the single second electrode 109.

Further, the second semiconductor layer 105 can be an i-type or p-type etch stop layer, an InP layer, or a combination thereof (the upper part can be an etch stop layer, the lower part can be an InP layer). As the etch stop layer, a mixed crystal material having wet etching selectivity with InP, such as InGaAsP, can be used. Various material systems can be used for the active layer 104 according to the application. For example, in the case of LD or SOA, it is conceivable to use a multiple quantum well (MQW) having excellent gain characteristics. In this case, an InGaAlAs system or an InGaAsP system is typically used. On the other hand, when it is desired to obtain a wider-band gain spectrum in SOA or when it is desired to obtain a large absorption coefficient in PD, a uniform bulk material can be obtained.

It is assumed that various items other than the above-mentioned features (for example, the thickness of each semiconductor layer, the the height of third semiconductor layers, the manufacturing method, etc.) follow those of PTL 1.

Hereinafter, the characteristics of the semiconductor optical device according to an embodiment will be described.

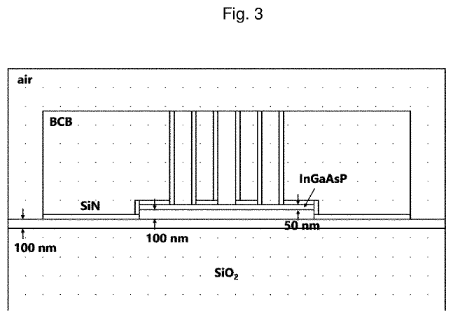

First, a structure for high power in which the width of the active layer 104 is relatively wide will be described. As a specific example, a structure in which mode calculation is performed is shown in FIG. 3. This is an example of the case where the active layer 104 is exposed as shown in FIG. 1. The width of the active layer 104 is defined as W₂=2.0 μm, and the width of each of the plurality of third semiconductor layers is defined as W_{1,i}=W₁=200 nm. For the sake of simplicity, the arrangement intervals G_{i,(i+1)}=G of the plurality of third semiconductor layers are all defined as a common value G. Other structural parameters and materials used are as shown in the diagram.

Although FIG. 3 shows an example in which three third semiconductor layers are used as an example, four types of calculations were performed for N=1, 2, 3, 4. N=1 corresponds to the structure of PTL 1, and in this case, the parameter of the interval between the third semiconductor layers adjacent to each other does not mean anything. When G=0 nm in N=2, 3, 4, the N third semiconductor layers are directly connected without a gap, and this is a structure in which only one third semiconductor layer having a width N×W1 is formed, which, in other words, corresponds to a structure in which the third semiconductor layer has a remarkably large width in the structure of PTL 1.

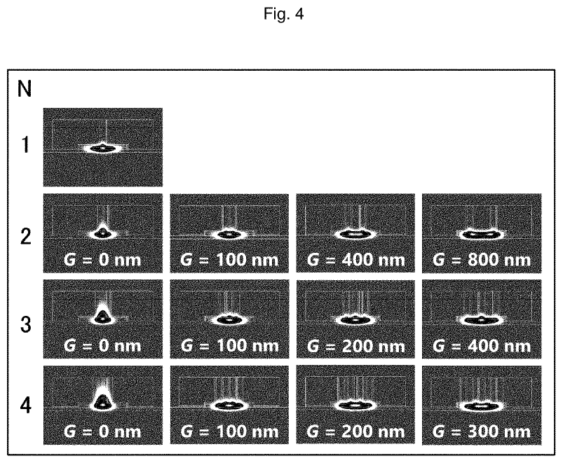

FIG. 4 shows the intensity distribution of the base mode calculated under various third semiconductor layer intervals G. In the case of G=0 nm, the mode is largely absorbed to the third semiconductor layer side as a result of the width of the third semiconductor layer being increased. On the other hand, when G is widened, the absorption of the mode by the third semiconductor layer is significantly reduced though the total width N×W₁ of the third semiconductor layers is common, and good optical confinement in which most of the mode is localized in the semiconductor thin film can be obtained.

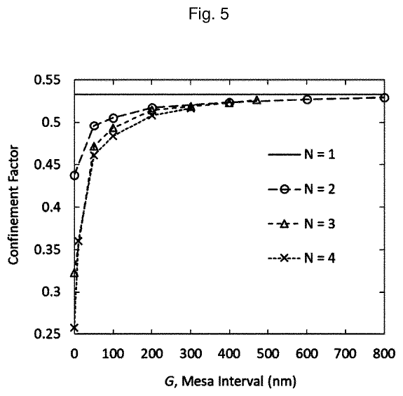

FIG. 5 is a diagram in which an optical confinement coefficient for the active layer 104 is plotted as a function of the intervals G of the third semiconductor layers adjacent to each other. When G is small, optical confinement is remarkably reduced especially at a level where the total width of N=3 and 4 is large. On the other hand, by widening G, optical confinement is remarkably recovered in any number N of third semiconductor layers. As a concrete example, when the optical confinement coefficient of N=1 is 100%, the optical confinement coefficient is 99.4% when N=2, G=800 nm, 98.1% when N =3, G =400 nm, and 96.9% when N=4, G=300 nm, so a very good optical confinement coefficient comparable to that of N=1 is obtained.

On the other hand, the resistance component r_{p-InP} (per unit length in the optical axis direction) of the third semiconductor layers composed of p-InP controlling the element resistance in this structure is determined by the dimensions of the third semiconductor layers as well known, and is given by the following formula.

$${r}_{p - InP} = {ρ}_{p - InP} \frac{{H}_{1}}{{NW}_{1}} \qquad [ Math . 1 ]$$

In the formula, ρ_{p-Inp} is a resistivity of a region of the third semiconductor layers composed of p-InP, and H₁ is the height of the third semiconductor layers. That is, according to the structure proposed by the present invention, it is possible to reduce the resistance values of the plurality of third semiconductor layers to 1/N times while maintaining the optical confinement at a value as high as that of the conventional structure (N=1 case). In the conventional structure, it is difficult to achieve both high optical confinement and low element resistance, but it can be said that the present invention breaks the trade-offs.

In addition to this, the present invention also provides the effect of realizing current injection with good uniformity into the entire active layer 104. That is, in the conventional structure, since a third semiconductor layer serving as a hole injection source exists only in a central portion of the active layer 104, holes are intensively supplied to the vicinity of the center of the active layer 104, so a large gain cannot be obtained easily in the vicinity of the left end and the right end, resulting in, in some cases, local loss of light.

On the other hand, in the structure according to the present invention, as is apparent from the arrangement of the plurality of third semiconductor since layers, the plurality of third semiconductor layers play a role of supplying holes to the active layer 104 in the vicinity of each of the third semiconductor layers, holes are uniformly supplied to the entire active layer 104. This feature has a desirable effect not only in the case of injecting a current in the use of LD, SOA, and the like. But also in the case of applying a reverse bias in the use of PD and the like. That is, in the PD, it is important from the viewpoint of the characteristics that photocarriers generated by absorption of light are quickly extracted from the active layer 104, but in this structure, photocarriers (holes) generated at each portion of the active layer 104 can be quickly extracted by the third semiconductor layer in the vicinity of each portion.

Further, the present invention provides an effect of distributing modes of light uniformly over the entire active layer 104. That is, as seen in the example of FIG. 4, in the conventional structure of N=1, the mode of light is restricted near the center of the active layer 104 by the single third semiconductor layer formed at the center of the active layer 104, and the intensity of light is remarkably weakened near both ends of the active layer 104. This means that the light does not feel the presence of the active layer 104 near both ends, and that the region does not effectively function as the active layer 104 for light emission and absorption. This hinders the purpose of increasing the power by widening the width of the active layer 104.

On the other hand, in the structure according to the present invention, be remarkably seen in in the mode distributions such as N=2, G=800 nm, N=3, G=400 nm, N=4, G=300 nm and so on, by arranging the outermost third semiconductor layer (i=1, N) in the vicinity of both ends of the active layer 104, the mode of light spreads in the x-direction in such a manner as to be dragged by these layers, and overlaps with a wider range of the entire active layer 104. Thus, most of the entire active layer 104 can effectively contribute to light emission and light absorption, and high power can be achieved by expanding the width of the active layer 104.

Next, a configuration for a lateral single mode in which the width of the active layer 104 is relatively narrow will be described. In the above description, since the width of the active layer 104 is relatively wide and the right and left sides of the Mesa structure in which the active layer 104 is disposed are clad with the low refractive index material, the lateral multi-mode is attained, and the higher-order mode such as the TE10 mode and the TE20 mode has strong optical confinement in the active layer 104.

This may cause the problem of multimode oscillation particularly when the present structure is applied to an LD. In general, in order to avoid the problem of the lateral multi-mode in a thin-film structure (including a conventional lateral injection structure or a longitudinal injection structure of a single third semiconductor layer), a structure may be used in which the active layer 104 as shown in FIG. 2 is embedded in the second semiconductor layer 105, the fourth semiconductor layer 111, and the fifth semiconductor layer 112, to make the width W₂ of the active layer 104 sufficiently narrow and make the width W_{side} of the fourth semiconductor layer 111 and the fifth semiconductor layer 112 on the right and left sides of the active layer 104 sufficiently wide.

Typically, W₂ is 800 nm or less and W_{side} is 1000 nm or more. With such a structure, optical confinement into the active layer 104 in the higher-order mode is reduced, and a good lateral single mode property is obtained. According to the present invention, it is possible to obtain a strong optical confinement in the base mode and a low element resistance per volume of the active layer can be achieved without impairing the good lateral single mode property in the above-described structure.

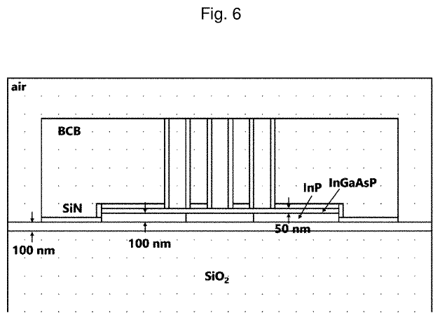

FIG. 6 shows a structure in which the mode is calculated as a specific example. The material system and the thickness of each layer used are common to those shown in FIG. 3. The width of the active layer 104 and the widths of the fourth and fifth semiconductor layers 111 and 112 on the right and left sides thereof are defined as W₂=800 nm and W_{side}=1000 nm, respectively. The width of each of the plurality of third semiconductor layers is defined as W_{1,i}=W₁=200 nm in common, and for simplicity, the interval between the third semiconductor layers adjacent to each other is defined as G_{i,(i+1)}=G all of which are defined as a common value G.

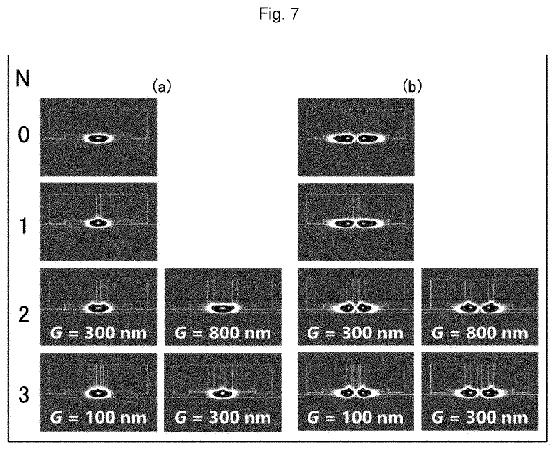

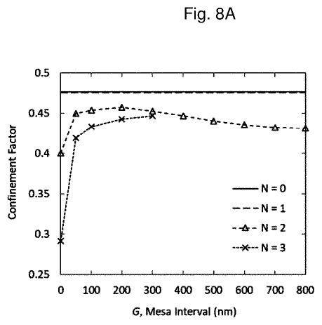

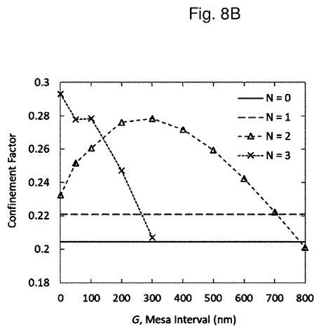

Although FIG. 6 shows a structure of N=3 as an example, four types of calculations were performed for N=0, 1, 2, 3. N=0 corresponds to a horizontal injection structure, and N=1 corresponds to a vertical injection structure of PTL 1. The intensity distributions of the TE00 mode (base mode) and TE10 mode obtained by the calculations are shown in FIG. 7(a) and FIG. 7(b). FIGS. 8A and 8B show the optical confinement coefficients of the TE00 mode and the TE10 mode into the active layer 104 in each case as a function of the interval G between the third semiconductor layers adjacent to each other.

First, as for the base mode, it is understood that good optical confinement which is comparable to the conventional structure (N=0, 1) is obtained in the structure (N=2, 3) of the present invention. Next, it is understood that the TE10 mode spreads to the fourth semiconductor layer 111 and the fifth semiconductor layer 112 when N=0, 1, and the overlap with the active layer 104 is small. The optical confinement coefficient at N=0 (N=1) is 0.477 (0.476) in the TE00 mode and 0.205 (0.221) in the TE10 mode, and in the conventional structure, the optical confinement in the high-order mode is significantly smaller than that in the base mode.

On the other hand, in N=2 and 3, two intensity peaks characteristic of the TE10 mode are distributed so as to be attracted to the third semiconductor layer. As a result, as shown in the plot of FIG. 8(b), in a structure in which the interval between the third semiconductor layers adjacent to each other is narrow and the expression (1) is satisfied, the TE10 mode is relatively strong and localized in the active layer 104, but in a structure in which the interval between the third semiconductor layers adjacent to each other is wide and the condition of the expression (1) is not satisfied, localization to the active layer 104 in the TE10 mode is reduced.

That is, by placing the outer third semiconductor layer (for example, i=1, N) at a position outside the active layer 104, that is, by bringing the third semiconductor layer into a state not satisfying the condition of the expression (1), the intensity distribution of the higher-order mode is drawn to a portion outside the active layer 104 while maintaining high optical confinement of the base mode, thereby reducing the optical confinement. Indeed, under the conditions of N=2, G=800 nm and N=3, G=300 nm, as exemplified also in FIG. 7, the optical confinement coefficient of the TE10 mode is 0.201 and 0.207, which is reduced to the same degree as or less than N=0, 1.

In the structure in which the third semiconductor layer is located outside the active layer 104, the efficiency of current injection into the active layer 104 is reduced. More specifically, holes may be injected into the fourth semiconductor layer 111 and the fifth semiconductor layer 112 on the left and right sides of the active layer 104, and the regions may become parallel current leakage paths. However, the fourth semiconductor layer 111 and the fifth semiconductor layer of semi-insulating 112 are composed semiconductors such as InP doped with Fe, current constriction to the active layer 104 can be performed. In this case, a hole injected from the outer third semiconductor layer is guided by a current constriction structure by the fourth semiconductor layer 111 and the fifth semiconductor layer 112 via the second semiconductor layer 105 above the active layer 104, and flows to the active layer 104 located at the center of the device.

Therefore, the present invention can be applied to a case in which the width of the active layer 104 is approximately the same as a typical size (specifically, approximately 800 nm or less) in the conventional lateral injection thin-film structure, and in this case, strong optical confinement in the base mode and low element resistance per volume of the active layer can be achieved while maintaining a good lateral single mode property comparable to the conventional structure. In this way, the configuration in which the width of the active layer 104 is relatively narrow is not always suitable for high power of a device, but since the maximum value of the amount of current which can be injected into the unit active layer volume is increased by reduction of the element resistance, the benefit of increasing the modulation speed in the direct modulation LD, for example, is obtained.

As described above, according to the present invention, since the plurality of third semiconductor layers for current injection are provided on the second semiconductor layer on the active layer, the width of the active layer can be expanded by satisfying the low element resistance per volume of the active layer, the good uniformity of the current injection distribution in the entire active layer, and the uniformity of the mode distribution of light.

According to the present invention, by arranging a plurality of the subdivided third semiconductor layers, it is possible to achieve both strong optical confinement of the base mode and a low element resistance per volume of the active layer. When the plurality of third semiconductor layers each having a narrow width are arranged at appropriate intervals, the trade-offs between optical confinement and element resistance in the conventional structure can be broken by making a concrete device structure by paying attention to a new finding that the base mode is not largely absorbed by the third semiconductor layers.

According to the present invention, expansion of a base mode shape by the plurality of third semiconductor layers can be effectively utilized. By paying attention to a new finding that the based mode shape is expanded in the lateral direction so as to be attracted to the active layer when the outermost third semiconductor layer is disposed near both ends of the active layer, and by utilizing such characteristics, the base mode can be distributed thoroughly over the entire active layer to enable the formation of the mode suitable for high power.

According to the present invention, by effectively utilizing deformation of a high-order mode shape caused by arranging the third semiconductor layer outside the region of the active layer, good lateral single mode property can be secured. By paying attention to a new finding that the intensity distribution in the TE10 mode is biased outside the active layer in a form of being attracted by the third semiconductor layer when intentionally arranging the third semiconductor layer outside the region of the active layer, and by utilizing such characteristics, the optical confinement of the high-order mode can be reduced significantly while maintaining the optical in the base mode high.

Note that it is clear that the present invention is not limited to the embodiments described above, and that within the technical concept of the present invention, many modifications and combinations can be implemented by those skilled in the art.

### REFERENCE SIGNS LIST

101 Substrate
102 First cladding layer
103 First semiconductor layer
104 Active layer
105 Second semiconductor layer
106-1, 106-2, 106-3, 106-N Third semiconductor layer
107-1, 107-2, 107-3, 107-N Contact layer
108 First electrode
109 Second electrode
110 Second cladding layer
111 Fourth semiconductor layer
112 Fifth semiconductor layer

1. A semiconductor optical device, comprising:
a first cladding layer formed on a substrate;
a first semiconductor layer of a first conductivity type formed on the first cladding layer;
an active layer formed on the first semiconductor layer;
a second semiconductor layer of one of an i-type and second conductivity type formed on the active layer in contact with the active layer;
a plurality of third semiconductor layers of a second conductivity type formed on the second semiconductor layer;
a first electrode electrically connected to the first semiconductor layer;
a second electrode electrically connected to the plurality of third semiconductor layers; and
a second cladding layer formed between the first semiconductor layer and the second electrode,
wherein the plurality of third semiconductor layers are arranged in a direction perpendicular to a waveguide direction and parallel to a plane of the substrate.

2. The semiconductor optical device according to claim 1, further comprising
a fourth semiconductor layer and a fifth semiconductor layer formed on the first semiconductor layer in contact with both side surfaces of a ridge pattern formed by the active layer along the waveguide direction.

3. The semiconductor optical device according to claim 1, further comprising
a plurality of contact layers formed on each of the plurality of third semiconductor layers,
wherein the second electrode is formed on the plurality of third semiconductor layers via the plurality of contact layers.

4. The semiconductor optical device according to claim 2, wherein the fourth semiconductor layer and the fifth semiconductor layer are made of one of non-conductive semiconductor and low-conductive semiconductor.

5. The semiconductor optical device according to claim 2, further comprising
a plurality of contact layers formed on each of the plurality of third semiconductor layers,
wherein the second electrode is formed on the plurality of third semiconductor layers via the plurality of contact layers.

6. The semiconductor optical device according to claim 4, further comprising
a plurality of contact layers formed on each of the plurality of third semiconductor layers,
wherein the second electrode is formed on the plurality of third semiconductor layers via the plurality of contact layers.
